(19) United States
(12) Patent Application Publication
(10) Pub. No.: US 2013/0320453 A1
(43) Pub. Date: Dec. 5, 2013

(54) AREA SCALING ON TRIGATE TRANSISTORS

(71) Applicants: Abhijit Jayant Pethe, Hillsboro, OR (US); Justin S. Sandford, Tigard, OR (US); Christopher J. Wiegand, Portland, OR (US); Robert D. James, Portland, OR (US)

(72) Inventors: Abhijit Jayant Pethe, Hillsboro, OR (US); Justin S. Sandford, Tigard, OR (US); Christopher J. Wiegand, Portland, OR (US); Robert D. James, Portland, OR (US)

(21) Appl. No.: 13/487,111

(22) Filed: Jun. 1, 2012

(51) Int. Cl. H01L 21/336; H01L 27/088

(52) U.S. Cl. 257/368; 438/299; 257/E21.409; 257/E27.06

(57) ABSTRACT

Improving an area scaling on tri-gate transistors is described. An insulating layer is deposited on a fin on a substrate. The insulating layer is recessed to expose the fin. The corner of the fin is rounded off using a noble gas. A gate dielectric layer is deposited on the rounded corner. The radius of curvature of the corner is controllable by adjusting a bias power to the substrate. The radius of curvature of the corner is determined based on the width of the fin to reduce an area scaling of the array.

### FIELD

Embodiments of the invention relate to the field of electronic device manufacturing; and more specifically, to fabrication of tri-gate arrays.

### BACKGROUND

Short-channel effects are the major limiting factors of downscaling of transistor dimensions. The short-channel effects occur due to the decreased length of the transistor channel between source and drain regions. The short-channel effects can severely degrade the performance of the semiconductor transistor. Because of short-channel effects, the electrical characteristics of the transistor, for example, a threshold voltage, subthreshold currents, and current-voltage characteristics become difficult to control with the gate electrode.

Generally, tri-gate transistors provide better control over the electrical characteristics than a planar transistor. A typical tri-gate transistor has a fin formed on a silicon substrate. The gate electrode with underlying gate dielectric covers a top and two opposing sidewalls of the fin. A source and a drain are formed in the fin at opposite sides of the gate electrode. Generally, the tri-gate transistor provides three conductive channels along the top and the two opposing sidewalls the fin. This effectively gives the tri-gate transistor substantially higher performance than the conventional planar transistors. A typical fin has sharp corners, for example, between the top surface and sidewalls to increase control over the electrical characteristics of the transistor. The sharp corners of the fin increase the gate electric field when compared to a planar transistor. The electric field enhancement at the sharp fin corners, however, increases the probability of the gate dielectric breakdown. The time dependent dielectric breakdown (TDDB) measurements for large transistor arrays indicate that because of the increased probability of the gate dielectric breakdown the tri-gate transistor arrays fail much faster than planar transistor arrays.

### BRIEF DESCRIPTION OF THE DRAWINGS

Embodiments of the invention may best be understood by referring to the following description and accompanying drawings that are used to illustrate embodiments of the invention. In the drawings:

FIG. 1 is a perspective view of a tri-gate transistor according to one embodiment of the invention;

FIG. 2A is a cross-sectional view of a wafer to provide a tri-gate transistor array according to one embodiment of the invention;

FIG. 2B is a view similar to FIG. 2A, after fins on a substrate are formed according to one embodiment of the invention;

FIG. 2C is a view similar to FIG. 2B, after an electrically insulating layer is deposited on the fins according to one embodiment of the invention;

FIG. 2D is a view similar to FIG. 2B, after an electrically insulating layer is polished back according to one embodiment of the invention;

FIG. 2E is a view similar to FIG. 2D after insulating layer that fills the spaces between the fins is recessed according to one embodiment of the invention;

FIG. 2F is a view similar to FIG. 2E, after the corners of the fins are rounded off according to one embodiment of the invention;

FIG. 2G is a view similar to FIG. 2F, after a gate dielectric layer is deposited on the fins according to one embodiment of the invention;

FIG. 2H is a view similar to FIG. 2G after a gate electrode is deposited on the gate dielectric layer according to one embodiment of the invention;

FIG. 3 is a diagram of a sputtering system according to one embodiment of the invention;

FIG. 4 is a graph showing a relative electric field in a gate dielectric versus a corner radius of curvature of a fin for a tri-gate transistor according to one embodiment of the invention;

FIG. 5 shows exemplary images of the fins for the tri-gate array before and after rounding off the corners according to one embodiment of the invention;

FIG. 6 shows an exemplary area scaling chart for wafers according to one embodiment of the invention;

FIG. 7 illustrates a computing device in accordance with one embodiment of the invention.

### DETAILED DESCRIPTION

In the following description, numerous specific details, for example, specific materials, structures, dimensions of the elements, processes, etc. are set forth in order to provide thorough understanding of one or more embodiments of the present invention. It will be apparent, however, to one of ordinary skill in the art that the one or more embodiments of the present invention may be practiced without these specific details. In other instances, microelectronic device fabrication processes, techniques, materials, equipment, etc., have not been described in great details to avoid unnecessarily obscuring of this description. Those of ordinary skill in the art, with the included description, will be able to implement appropriate functionality without undue experimentation.

Reference throughout the specification to one embodiment or an embodiment means that a particular feature, structure, or characteristic described in connection with the embodiment is included in at least one embodiment. Thus, the appearance of the phrases in one embodiment or in an embodiment in various places throughout the specification are not necessarily all referring to the same embodiment. Furthermore, the particular features, structures, or characteristics may be combined in any suitable manner in one or more embodiments.

Methods and apparatuses to improve a time dependent dielectric breakdown (TDDB) area scaling on tri-gate transistors is described. The fin profile is changed to round off the corners to significantly reduce the electric field across the gate dielectric. The reduced electric field reduces probability of gate dielectric breakdown and hence improves gate reliability without any transistor performance penalty, as described in further detail below.

An insulating layer is deposited on a fin on a substrate. The insulating layer is recessed to expose the fin. The corner of the fin is rounded off using a noble gas, as described in further detail below. The radius of curvature of the corner is controllable by adjusting a bias power to the substrate. The radius of curvature of the corner is determined based on the width of the fin. A gate dielectric layer is deposited on the rounded corner. The radius of curvature of the corner is determined based on the width of the fin to reduce an area scaling of the array by at least 60%.

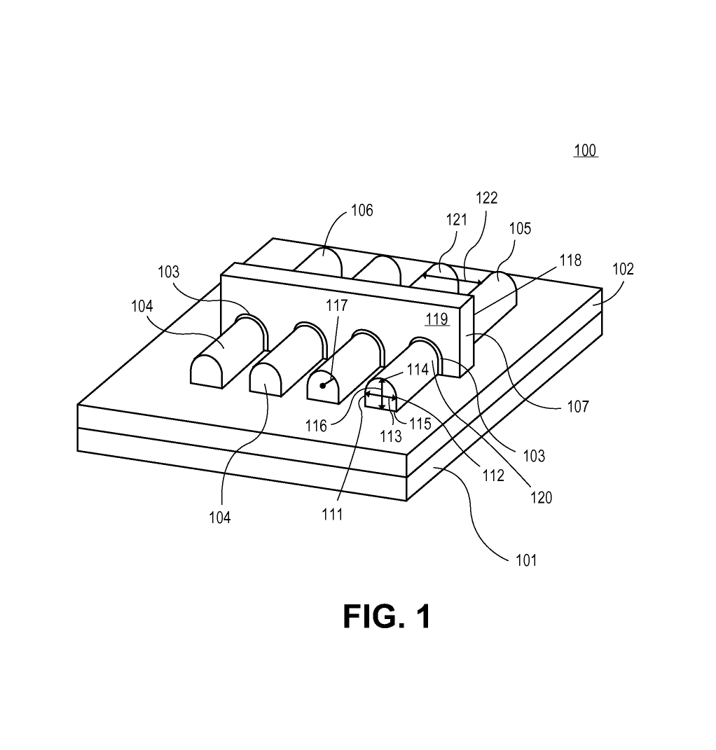

FIG. 1 is a perspective view of a tri-gate transistor 100 according to one embodiment of the invention. As shown in FIG. 1, a tri-gate transistor 100 includes a substrate 101 having semiconductor fins, such as a fin 105 and a fin 121, and an electrically insulating layer 102 over substrate 101 adjacent to the fins. In at least one embodiment, tri-gate transistor 100 is a part of a tri-gate transistor array that includes multiple tri-gate transistors formed on a substrate 101. As shown in FIG. 1, the fins, such as fin 105 and fin 121 are spaced by a pitch 122. In one embodiment, the pitch 122 is determined by a design of the tri-gate array. In one embodiment, the pitch 122 is from about 30 nanometers (nm) to about 100 nm. Transistors are formed based on the fins. In one embodiment, substrate 101 includes a monocrystalline silicon (Si), germanium (Ge), silicon germanium (SiGe), a III-V materials, e.g., gallium arsenide (GaAs) based materials, or any combination thereof. In one embodiment, substrate 101 includes a semiconductor-on-isolator (SOI) substrate including a bulk lower substrate, a middle insulation layer, and a top monocrystalline layer. The top monocrystalline layer may comprise any material listed above for the bulk monocrystalline substrate. In one embodiment, tri-gate transistor 100 is coupled to one or more layers of metallization (not shown). The one or more metallization layers can be separated from adjacent metallization layers by dielectric material, e.g., interlayer dielectric (ILD) (not shown). The adjacent metallization layers may be electrically interconnected by vias (not shown). The tri-gate transistor array including multiple transistors, such as tri-gate transistor 100 can be formed on any well-known insulating substrate such as substrates formed from silicon dioxide, nitrides, oxides, and sapphires.

In one embodiment, electrically insulating layer 102 is an oxide layer, e.g., silicon dioxide. In one embodiment, insulating layer 102 is a shallow trench isolation (STI) layer to provide field isolation regions that isolate for example one device (e.g., a transistor) from other devices (e.g., transistors or other devices) on substrate 101. In one embodiment, the thickness of the layer 102 is in the approximate range of 500 angstroms (Å) to 10,000 Å. Shallow trench isolation layers are known to one of ordinary skill in the art of electronic device manufacturing.

As shown in FIG. 1, the fins, such as fin 105 protrude from a top surface of insulating layer 102. In one embodiment, each of the fins, such as fin 105 has a height, such as a height 116 that can be defined as a distance between a top surface 115 of the insulating layer 102 and a top surface 114 of the fin. In one embodiment, the height of each of the fins, such as fin 105, is from about 500 Å to about 5,000 Å. In one embodiment, the height of the fins, such as fin 105, is from about 500 Å to about 1500 Å. In one embodiment, each of the fins, such as fin 105 is a semiconductor material that is degenerately doped. In another embodiment, semiconductor fin 105 is made electrically conducting through silicidation, or the like. In one embodiment, insulating layer 102 comprises an interlayer dielectric (ILD), e.g., silicon dioxide. In one embodiment, insulating layer 102 may include polyimide, epoxy, photodefinable materials, such as benzocyclobutene (BCB), and WPR-series materials, or glass. In one embodiment, insulating layer 102 is a low permittivity (low-k) ILD layer. Typically, low-k is referred to the dielectrics having dielectric constant (permittivity k) lower than the permittivity of silicon dioxide.

Semiconductor fins, such as fin 105 can be formed of any well-known semiconductor material, such as but not limited to silicon (Si), germanium (Ge), silicon germanium (Siₓ Ge_{y}), gallium arsenide (GaAs), InSb, GaP, GaSb and carbon nanotubes. Semiconductor fin 105 can be formed of any well-known material which can be reversibly altered from an insulating state to a conductive state by applying external electrical controls. In one embodiment, the semiconductor fins, such as fin 105 are single crystalline material fins. In one embodiment, the semiconductor fins, such as fin 105 are polycrystalline material fins. As shown in FIG. 1, insulating layer 102 insulates the semiconductor fins from each other. As shown in FIG. 1, each of the fins, such as fin 105 has a pair of opposing sidewalls 111 and 112 separated by a distance which defines a semiconductor fin width 113. In one embodiment, the fin width 113 is in an approximate range from about 5 nm to about 50 nm. In one embodiment, the length of the fins is greater than the width and is determined by a design. In one embodiment, the length of the fins is from about 50 nm to hundreds of microns.

As shown in FIG. 1, top surface 115 of the fin is above a surface 115 of the insulating layer 102. As shown in FIG. 1, the corners between a top surface of the fin, such as a top surface 114 and opposing sidewalls of the fin, such as sidewalls 111 and 112 are rounded. The rounded corners have a radius of curvature, such as a radius of curvature 117. In one embodiment, the radius of curvature of the rounded corners is determined based on the width of the fin. In one embodiment, the radius of curvature is at least 20 percent (%) of the width of the fin. For example, if the fin width is about 20 nm, the radius of curvature is at least about 4 nm, as described in further detail below. In one embodiment, the radius of curvature of the rounded corners of the fin 105 is determined to reduce the area scaling of the transistor array by at least 60%, as described in further detail below.

In an embodiment, the fin 105 has a width 113 that is less than 30 nanometers and ideally less than 20 nanometers. In an embodiment, the fin height 116 above the top surface of the insulating layer 102 is in an approximate range from about 5 nm to about 500 nm. In at least one embodiment, the height 116 and width 113 are independent.

In an embodiment, the fins, e.g., fin 105 and fin 121 have a high aspect ratio. Typically, the aspect ratio of the fin is defined as the ratio of the fin height, e.g., height 116 to the fin width, e.g., width 113. In at least some embodiments, the fin height, such as height 116 is about 50 nm to about 500 nm and the fin width, e.g., width 113 is from about 5 nm to about 20 nm. In at least some embodiments, the fins, e.g., fins 105 and 121 have an aspect ratio from about 5:1 to about 25:1.

As shown in FIG. 1, a gate dielectric layer, such as a gate dielectric layer 103 is deposited on each of the fins, such as fin 105 covering the rounded corners. The gate dielectric layer, such as gate dielectric layer 103, is formed on and around three sides of the semiconductor fins, such as fin 105. As shown in FIG. 1, gate dielectric layer 103 is formed on or adjacent to sidewall 111, on top surface 114 and on or adjacent to sidewall 112 of fin 105. Gate dielectric layer 103 can be any well-known gate dielectric layer.

In one embodiment, gate dielectric layer 103 is a high-k dielectric material having a dielectric constant greater than the dielectric constant of silicon dioxide. In one embodiment, electrically insulating layer 103 comprises a high-k dielectric material, such as a metal oxide dielectric. For example, gate dielectric layer 103 can be but not limited to tantalum pentaoxide (Ta₂O₅), and titantium oxide (TiO₂) zirconium oxide (ZrO₂), hafnium oxide (HfO₂), lanthanum oxide (La₂O₄), lead zirconium titanate (PZT), other high-k dielectric material, or a combination thereof. In one embodiment, a high-k gate dielectric layer 103 is deposited on or adjacent to the sidewalls 111, and 112, and top surface 114 of each of the silicon fins, such as silicon fin 105 covering the rounded corners having a radius of curvature, such as radius of curvature 117.

In an embodiment, the gate dielectric layer 103 is a silicon dioxide (SiO₂), silicon oxynitride (SiOₓN_{y}) or a silicon nitride (Si₃N₄) dielectric layer. In an embodiment, the thickness of the gate dielectric layer 103 is in the approximate range between about 2 Å to about 100 Å, and more specifically, between about 5 Å to about 30 Å.

As shown in FIG. 1, a gate electrode, such as a gate electrode 107 is deposited on the gate dielectric layer on each of the fins. Gate electrode 107 is formed over the multiple fins to provide a large gate width transistor. Gate electrode 107 is formed on and around the gate dielectric layer 103 as shown in FIG. 1. Gate electrode 107 is formed on or adjacent to gate dielectric 103 formed on sidewall 111 of semiconductor fin 105, is formed on gate dielectric 103 formed on the top surface 114 of semiconductor fin 105, and is formed adjacent to or on gate dielectric layer 103 formed on sidewall 112 of semiconductor fin 105.

As shown in FIG. 1, gate electrode 107 has a pair of laterally opposite sidewalls, such as a sidewall 118 and a sidewall 119 separated by a distance which defines the gate length of the fin transistor.

Gate electrode 107 can be formed of any suitable gate electrode material. In an embodiment, gate electrode 107 comprises of polycrystalline silicon doped to a concentration density between 1×10¹⁹ atoms/cm³ to 1×10²⁰ atoms/cm³. In an embodiment, the gate electrode can be a metal gate electrode, such as but not limited to, tungsten, tantalum, titanium, and their nitrides. It is to be appreciated, the gate electrode 107 need not necessarily be a single material and can be a composite stack of thin films, such as but not limited to a polycrystalline silicon/metal electrode or a metal/polycrystalline silicon electrode.

The source and gate regions, such as a source region 104 and a drain region 106 are formed at opposite sides of the gate electrode 107 in each of the fins, such as fin 105. Source region 104 and drain region 106 are formed in the fin 105 at opposite sides of gate electrode 107, as shown in FIG. 1. The source and drain regions, such as source region 104 and drain region 106 are formed of the same conductivity type such as N-type or P-type conductivity. In an embodiment, the source and drain regions, such as source region 104 and drain region 106 have a doping concentration of between 1×10¹⁹, and 1×10²¹ atoms/cm³. The source and drain regions, such as source region 104 and drain region 106 can be formed of uniform concentration or can include sub-regions of different concentrations or doping profiles such as tip regions (e.g., source/drain extensions). In an embodiment, the source and drain regions, such as source region 104 and drain region 106 have the same doping concentration and profile. In an embodiment, the doping concentration and profile of the source and drain regions, such as source region 104 and drain region 106 can vary in to obtain a particular electrical characteristic.

The portion of each of the fins located between the source region and drain regions, defines a channel region of a transistor of the array, such as a channel region 120. The channel region 120 can also be defined as the area of the semiconductor fin 105 surrounded by the gate electrode 107. At times however, the source/drain region may extend slightly beneath the gate electrode through, for example, diffusion to define a channel region slightly smaller than the gate electrode length (Lg). In an embodiment, channel region 120 is intrinsic or undoped.

In an embodiment, channel region 120 is doped, for example to a conductivity level of between 1×10¹⁶ to 1×10¹⁹ atoms/cm³. In an embodiment, when the channel region is doped it is typically doped to the opposite conductivity type of the source region 104 and the drain region 106. For example, when the source and drain regions are N-type conductivity the channel region would be doped to p type conductivity. Similarly, when the source and drain regions are P type conductivity the channel region would be N-type conductivity. In this manner a tri-gate transistor 100 can be formed into either a NMOS transistor or a PMOS transistor respectively. Channel regions, such as channel region 120 can be uniformly doped or can be doped non-uniformly or with differing concentrations to provide particular electrical and performance characteristics. For example, channel regions, such as channel region 120 can include well-known halo regions, if desired.

As shown in FIG. 1, tri-gate transistor 100 has a dielectric and a gate electrode surrounding the rounded semiconductor fins, such as fin 105 on three sides that provides three channels on each of the fins, one channel extends between the source and drain regions on one sidewall of the fin, such as sidewall 111, a second channel extends between the source and drain regions on the top surface of the fin, such as surface 114, and the third channel extends between the source and drain regions on the other sidewall of the fin, such as sidewall 112.

In an embodiment, the source regions of the transistor 100 are electrically coupled to higher levels of metallization (e.g., metal 1, metal 2, metal 3, and so on) to electrically interconnect various transistors of the array into functional circuits. In one embodiment, the drain regions of the transistor 100 are coupled to higher levels of metallization (e.g., metal 1, metal 2, metal 3, and so on) to electrically interconnect various transistors of the array together into functional circuits.

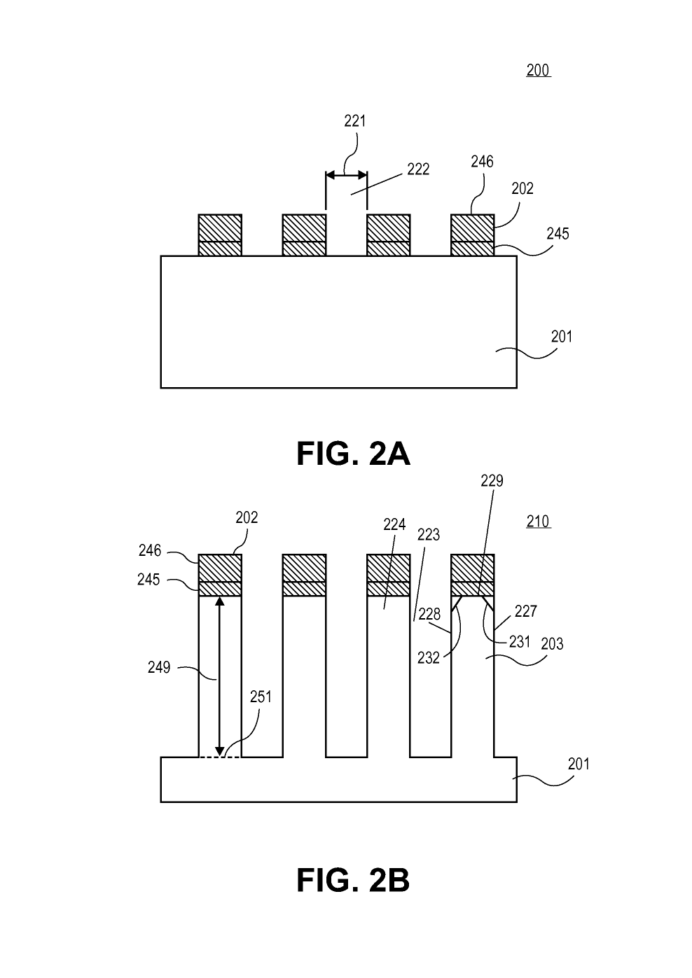

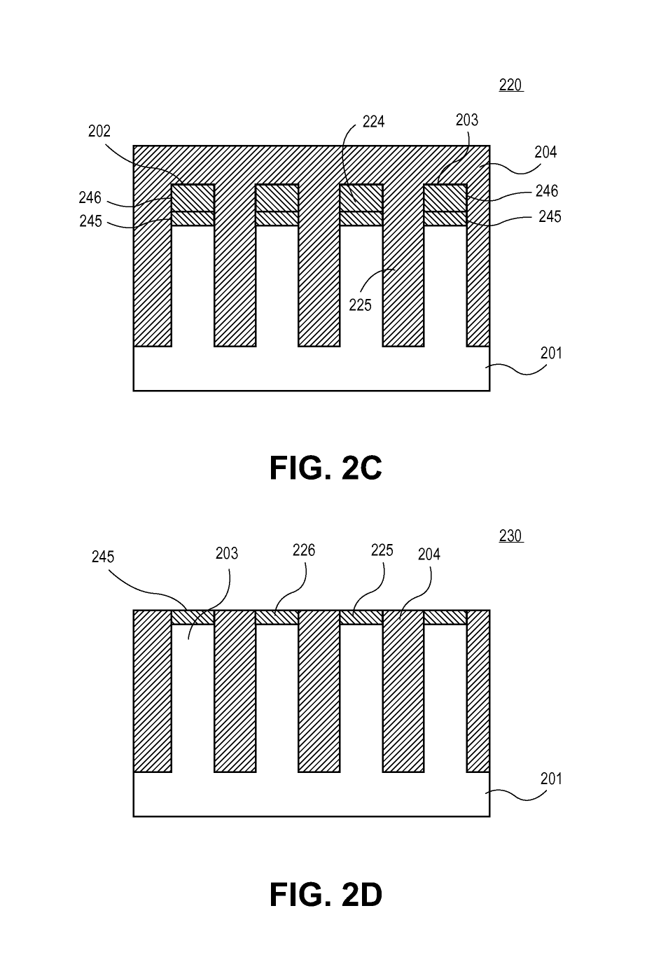

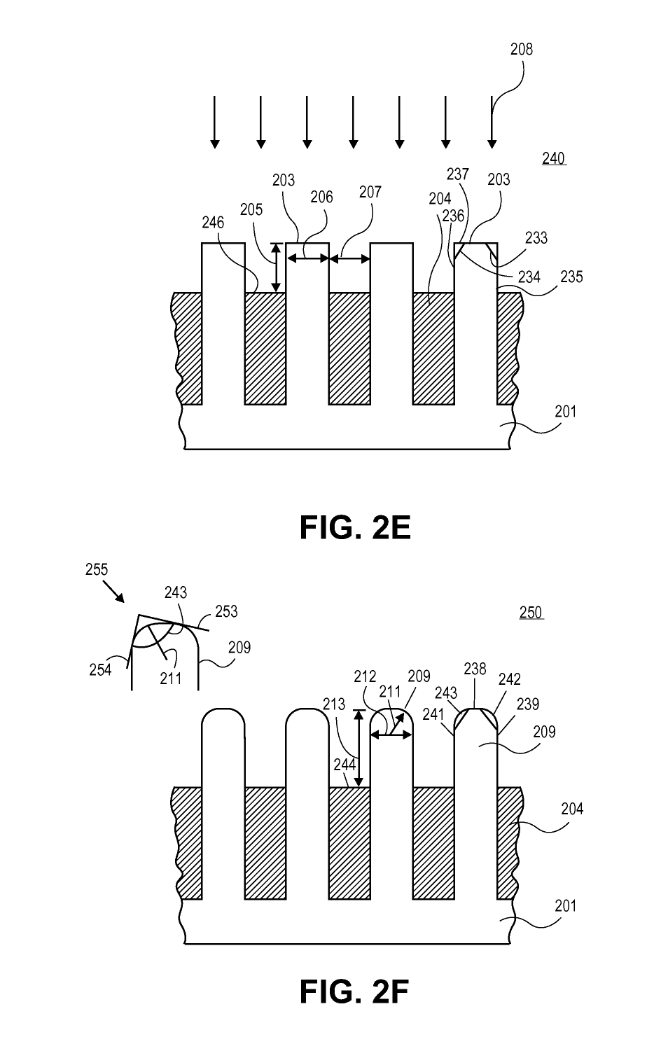

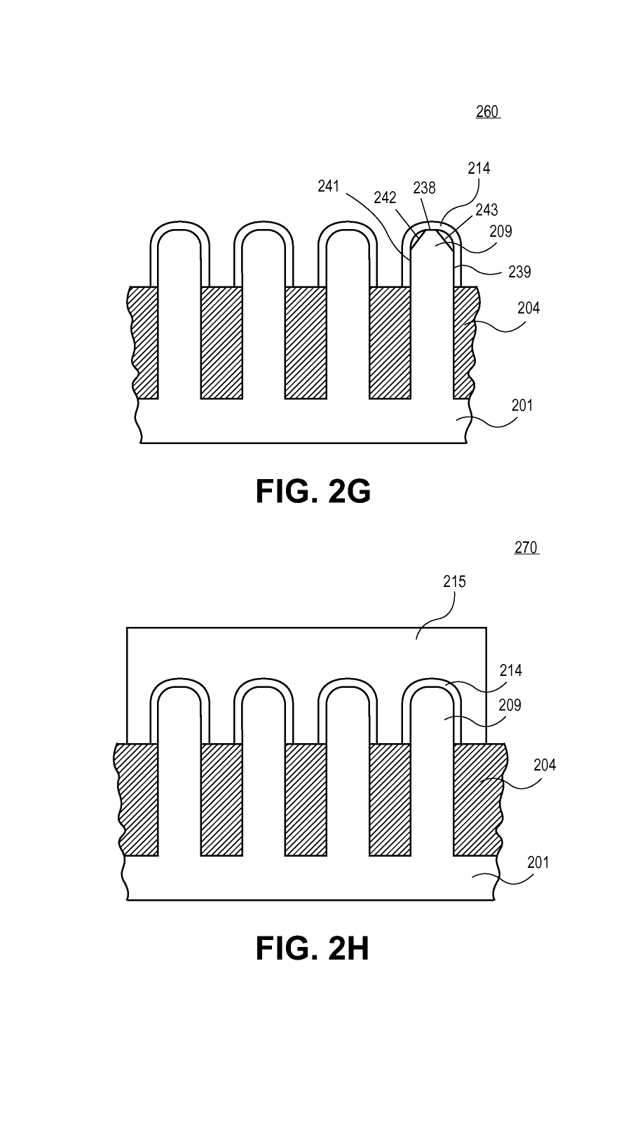

FIG. 2A is a cross-sectional view of a wafer 200 to provide a tri-gate transistor array according to one embodiment of the invention. As shown in FIG. 2A, a patterned hard mask 202 is deposited over a substrate 201. Substrate 201 can be any of but not limited to Si, Ge, SiₓGe_{y}, III-V materials, e.g., GaAs, InSb, GaP, GaSb and carbon nanotubes based materials, as described above. In one embodiment, the substrate 201 is a single crystalline material substrate, e.g., monocrystalline silicon substrate. In one embodiment, substrate 201 is a substrate 101 as depicted in FIG. 1. In one embodiment, the substrate 201 is a polycrystalline material substrate. The hard mask 202 is patterned to form openings. As shown in FIG. 2A, patterned hard mask 202 includes a hard mask layer 246 formed on a hard mask layer 245 on the substrate 201. In an embodiment, the hard mask layer 245 is a silicon dioxide layer or a high k metal oxide dielectric layer, for example, titanium oxide, hafnium oxide, or aluminum oxide. In one embodiment, the hard mask layer 245 is from about 1 nm to about 10 nm thick. In one embodiment, hard mask layer 246 is from about 10 nm to about 100 nm thick. Hard mask layers 245 and 246 may be formed by any suitable process, such as chemical vapor deposition (CVD), physical vapor deposition (PVD) or atomic layer deposition (ALD). The hard mask layers 245 and 246 may be patterned using any of suitable photolithography techniques known in the art of electronic device manufacturing.

The patterned hard mask 202 contains a pattern defining locations where semiconductor fins will be subsequently formed in the semiconductor substrate 201. The hard mask 202 has openings, such as an opening 222. In one embodiment, the size of openings in the hard mask, such as a size 221, defines a pitch between the fins of the tri-gate transistor array, as described above. In an embodiment, the pattern in the hard mask 201 defines a width of each of the fin of the fabricated array, as described above. In an embodiment, the semiconductor fins have a width less than or equal to 30 nanometers and ideally less than or equal to 20 nanometers. The fin width can be any of the fin widths as described above with respect to FIG. 1. Additionally, the hard mask can also include patterns for defining locations where source landing pads and drain landing pads, respectively, are to be formed. The landing pads can be used to connect together the various source regions and to connect together the various drain regions of the fabricated transistor. FIG. 2B is a view 210 similar to FIG. 2A, after fins on a substrate are formed according to one embodiment of the invention. After patterning the hard mask 202, semiconductor substrate 201 is etched through the openings, such as opening 222 to form fins, such as a fin 203. In an embodiment where substrate 201 is an SOI substrate, fins, such as a fin 203 are formed from the top monocrystalline semiconductor layer. Substrate 201 can be etched using any suitable etching technique, e.g., a dry etch or wet etch known to one of ordinary skill in the art of electronic device manufacturing.

As shown in FIG. 2B, fin 203 has a top surface 229, and opposing sidewalls 228 and 229. Patterned hard mask 202 having hard mask layer 246 on hard mask layer 245 is on the top surfaces of the fin, such as a top surface 229. As shown in FIG. 2B, a corner 231 is formed between top surface 229 and sidewall 227, and a corner 232 is formed between top surface 229 and sidewall 228. In one embodiment, each of the corners 231 and 232 is a sharp corner. In one embodiment, each of the corners 231 and 232 is substantially equal to 90°. In at least one embodiment, each of the corners 231 and 232 has a radius of curvature that is less than 10% of the width of the fin, e.g., for the width of the fin of 20 nm, the radius of curvature is less than 2 nm. In at least one embodiment, each of the corners 231 and 232 has a radius of curvature less than 10 nm. In one embodiment, source and drain landing pads (not shown) are formed in the substrate. In one embodiment, substrate 201 is etched through the opening in the hard mask to create a fin having a desired height, such as a height 249 relative to a bottom level of the trench between the fins, such as a level 251. In one embodiment, the height of the fin, such as height 249 is from about 5 nm to about 1000 nm. In one embodiment, the fins on substrate 201 are spaced by a pitch. As shown in FIG. 2B, a fin 203 and a fin 224 are spaced by a pitch 223. The pitch between the fins is described above. In one embodiment, the fins, e.g., fin 203 and 224 are tapered, such that the bottom of the fin is wider than the top of the fin. In one embodiment, the width at the top of the fins e.g., fin 203 and 224 is substantially the same as the width at the bottom of the fins. FIG. 2C is a view 220 similar to FIG. 2B, after an electrically insulating layer 204 is deposited over the fins according to one embodiment of the invention. The insulating layer 204 fills the gaps between fins and forms over the top surface of hard mask 202 on the fins, as shown in FIG. 2C. In an embodiment, insulating layer 204 can be any material suitable to insulate adjacent devices and prevent leakage from the fins. As shown in FIG. 2C, insulating layer 204 is deposited over the top surfaces of the fins filling the space, such as a space 225 between the fins. In one embodiment, electrically insulating layer 204 is an oxide layer, e.g., silicon dioxide, or any other electrically insulating layer determined by a design of the tri-gate array. In one embodiment, insulating layer 204 is a shallow trench isolation (STI) layer to provide field isolation regions that isolate one fin from other fins on substrate 201. In one embodiment, the thickness of the layer 204 is in the approximate range of 500 angstroms (Å) to 10,000 Å. The insulating layer 204 can be blanket deposited using any of techniques known to one of ordinary skill in the art of electronic device manufacturing, such as but not limited to a chemical vapour deposition (CVD), and a physical vapour deposition (PVP).

FIG. 2D is a view similar to FIG. 2B, after an electrically insulating layer is polished back according to one embodiment of the invention. In one embodiment, the insulating layer 204, which covers the fins, such as fin 203 is polished back by, for example, by a chemical-mechanical polishing (“CMP”), to expose top surfaces of the hard mask layer 245, such as a top surface 225. As shown in FIG. 2D, top surfaces of the hard mask layer 245, such as top surface 225, are substantially planar with the top surfaces of the insulating layer 204 that fills the space between the fins, such as a top surface 226. In an embodiment, hard mask layer 246 is removed by a polishing process, such as a CMP. In an embodiment, at least a portion of hard mask layer 245 is removed by a polishing process, such as a CMP.

FIG. 2E is a view similar to FIG. 2D after insulating layer 204 that fills the spaces between the fins is recessed according to one embodiment of the invention. As shown in FIG. 2E, patterned hard mask 202 including hard mask layers 245 and 246 is removed from the fins, such as fin 203. As shown in FIG. 2E, insulating layer 204 is recessed down to a predetermined depth that defines a height 205 of the fin, such as fin 203, relative to a reference surface, e.g., a top surface 246 of the insulation layer 204. In an embodiment, height 205 is determined by a design of the fin. In one embodiment, height 205 is in an approximate range of from about 5 nm to about 500 nm. In one embodiment, height 205 can be any of the fin heights as discussed above with respect to FIG. 1. As shown in FIG. 2E, a corner 233 is formed between a top surface 237 and a sidewall 235, and a corner 234 is formed between top surface 237 and sidewall 236. In one embodiment, each of the corners 233 and 234 is a sharp corner. In one embodiment, each of the corners 233 and 234 is substantially equal to 90°. In at least one embodiment, each of the corners 233 and 234 has a radius of curvature that is that is less than 10% of the width of the fin. In at least one embodiment, each of the corners 233 and 234 has a radius of curvature that is less than 10 nm.

In one embodiment, insulating layer 204 is recessed by a selective etching technique while leaving the fins, such as fin 203 intact. For example, insulating layer 204 can be recessed using a selective etching technique known to one of ordinary skill in the art of electronic device manufacturing, such as but not limited to a wet etching, and a dry etching with the chemistry having substantially high selectivity to the substrate 201. This means that the chemistry predominantly etches the insulating layer 204 rather than the fins of the substrate 201. In one embodiment, a ratio of the etching rates of the insulating layer 204 to the fins is at least 10:1. Next, the corners of the fins, such as corners 233 and 234 are rounded off using a gas 208, as shown in FIG. 2E.

FIG. 2F is a view similar to FIG. 2E, after the corners of the fins are rounded off according to one embodiment of the invention. As shown in FIG. 2F, a top portion of the fins, such as a fin 209 is rounded. As shown in FIG. 2F, a corner 242 between a top surface 238 and a sidewall surface 239 is a rounded corner, and a corner 243 between top surface 238 and a sidewall surface 241 is rounded. An enlarged top portion of the fin, such as fin 209 having a rounded corner, such as corner 243 is shown in insert 255. As shown in insert 255, corner 243 is formed by a tangent line 253 to top surface 238 and a tangent line 254 to side surface 241. In one embodiment, each of the corners 242 and 243 is substantially greater than 90°. In at least one embodiment, each of the corners of the fin has a radius of curvature, such as a radius 211 that is greater than 10% of the width of the fin, and more specifically, at least 20% of the width of the fin. For example, for the width of the fin about 20 nm, the radius of curvature of the fin is at least about 4 nm. In an embodiment, a radius of curvature, such as radius 211 is defined as a measure of the radius of the circular arc which best approximates the rounded corner of the fin, e.g., rounded corner 243. In at least one embodiment, each of the corners of the fin has a radius of curvature, such as radius 211 that is about 50% of the width of the fin. In one embodiment, the radius of curvature of the fin, such as radius 211 is adjusted by a sputter etching process to be in an approximate range between 20% and 50% of the width of the fin, such as width 212. In one embodiment, for the width of the fin about 20 nm, the radius of curvature is adjusted to be from about 4 nm to about 10 nm. In at least one embodiment, each of the corners of the fin has a radius of curvature that is greater than 10 nm, and more specifically, is at least 20 nm.

Referring back to FIG. 2E, the corners of the fin, such as corners 233 and 234 are gently etched while substantially preserving the height of the fin, such as, height 205. As shown in FIG. 2F, gentle etching by using gas 208 rounds off the corners of the fins to provide rounded corners, such as rounded corners 242 and 243. As shown in FIG. 2F, the height of the fin having rounded corners, such as a height 213 is substantially the same as the height of the fin before etching, such as height 205. In one embodiment, at least from about 90% to about 95% of the height of the fin, such as height 205 is preserved while the corners of the fins, such as corners 233 and 234 are gently sputter etched by an inert gas. In one embodiment, a height 213 of the rounded fin is defined as a distance from a top surface of the fin to a reference surface which is substantially planar, for example, with a top surface 244 of the insulating layer 204. In one embodiment, the rounding off the corners of the fins involves gently sputter etching the corners of the fins, such as corners 233 and 234 at a rate that substantially exceeds the rate of etching the surfaces of the fin, such as top surface 237 and opposing sidewalls 235 and 236. In one embodiment, the etching rate of the corners is at least two times greater than the etching rate of the surfaces of the fins.

In one embodiment, the corners of the fins, such as corners 233 and 234 are rounded off by a sputter etching process using a noble gas for example, argon (Ar), helium (He), neon (Ne), krypton (Kr), xenon (Xe), radon (Rn), any other inert gas, or a combination thereof. In another embodiment, the corners of the fins, such as corners 233 and 234 are rounded off using wet etching, dry etching techniques, such as a reactive ion etching (RIE), or a combination thereof.

In one embodiment, after rounding off the corners of the fins by sputter etching, a thin sacrificial dielectric layer (not shown) is formed on the top and sidewall surfaces of the fins, such as fin 209. The thin sacrificial dielectric layer covers the top and sidewall surfaces of the fins, such as top surface 238 and sidewall surfaces 239 and 241. In an embodiment, the thin sacrificial dielectric layer formed on the fins, such as fin 209 is a thermally grown silicon dioxide or silicon oxynitride dielectric layer. In one embodiment, the thin sacrificial dielectric layer formed on the fins, such as fin 209 is from about 10 Å to about 20 Å thick. In one embodiment, a thermal oxidation process grows a thicker oxide on the sidewall surfaces, such as surfaces 239 and 241 than on the top surfaces, such as top surface 238. Any well known thermal oxidation process can be used to form the thermally grown silicon oxide or silicon oxynitride film on the fins. When the thin sacrificial dielectric layer is formed by a thermal oxidation process, the rounded corners, e.g., rounded corners 242 and 243 are further-rounded by the oxidation process. Although the thin sacrificial dielectric on the fins, such as fin 209 is ideally a grown dielectric, the thin sacrificial dielectric can be a deposited dielectric, if desired.

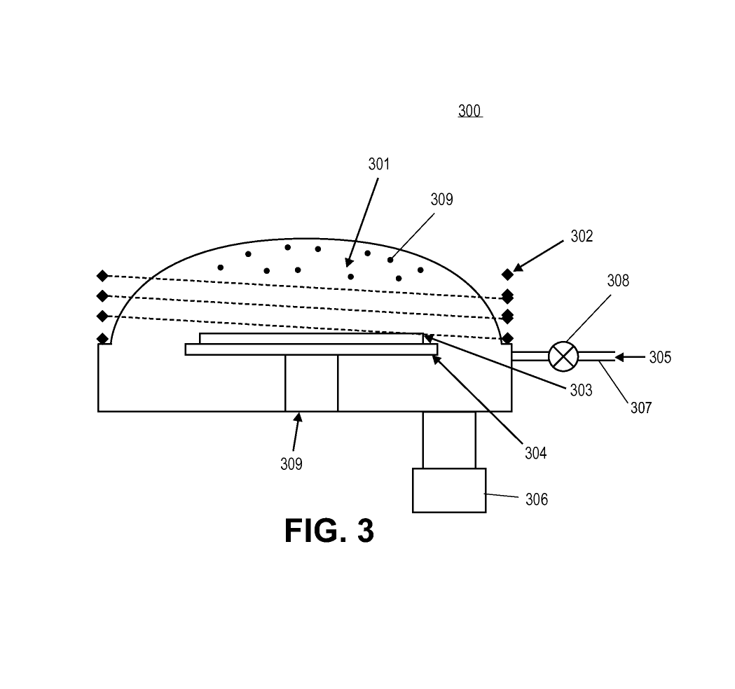

Next, the thin sacrificial dielectric layer formed on the fins, such as fin 209, is removed. In an embodiment the thin sacrificial dielectric layer formed on fins, such as fin 209 is removed using any of suitable techniques, e.g., wet etching, dry etching, or a combination thereof. FIG. 3 is a diagram of a sputtering system 300 according to one embodiment of the invention. As shown in FIG. 3, sputtering system 300 includes a chamber 301 having a wafer 303 positioned on a pedestal 304. In one embodiment, wafer 303 includes the fins, such as fin 203 and 209 formed on the substrate, such as substrate 201, as described herein. As shown in FIG. 3, a gas 305 is supplied to chamber 301 through an inlet 307 and a valve 308. The sputter chamber 301 has an outlet connected to a vacuum pump 306 to evacuate the air out of the sputter chamber. In one embodiment, gas 305 is a noble gas, such as but not limited to Ar, He, Ne, Kr, Xe, and Rn, as described herein. In one embodiment, the pressure in chamber 301 is controlled through the flow of gas 305. In one embodiment, the pressure of the gas 305 in the chamber 301 is from about 1 mtorr to about 5 mtorr. As shown in FIG. 3, inductively coupled plasma (ICP) coils 302 provide RF power to chamber 301 to ionize gas 305 to generate a plasma 309. The density of the plasma 309 to round off the fins as described herein can be controlled by the ICP coil RF power. In one embodiment, the ICP coils RF power to round off the fins as described herein is from about 150 to 250 W at a frequency of about 2 MHz.

As shown in FIG. 3, a RF pedestal bias power 309 is applied to wafer 303. In one embodiment, RF pedestal bias power 309 to control rounding off the fins, such as fin 209 is as low as possible. In one embodiment, RF pedestal bias power 309 to control rounding off the fins, such as fin 209 is from about 250 W to about 350 W at a frequency of about 13.56 MHz. In one embodiment, a DC bias voltage is applied to wafer 303 to round off the fins, such as fin 209, is from about 50V to about 100V relative to ground. In one embodiment, the radius of curvature of the fin, such as radius of curvature is adjustable by a sputter etching process. In one embodiment, the radius of curvature of the fin, such as radius of curvature 211 is controlled by adjusting RF pedestal bias power 304 applied to the wafer while maintaining the ICP coils RF power, DC bias voltage, and gas pressure unchanged. In one embodiment, sputtering system 300 is a bell jar sputtering system. Bell jar sputtering systems are known to one of ordinary skill in the art of electronic device manufacturing.

FIG. 2G is a view 260 similar to FIG. 2F, after a gate dielectric layer is deposited on the fins according to one embodiment of the invention. As shown in FIG. 2G, gate dielectric layer 214 is covers top surfaces, such as top surface 238, opposing sidewall surfaces, such as surfaces 239 and 241, and rounded corners, such as rounded corners 242 and 243 of the fins, such as fin 209. The gate dielectric layer, such as gate dielectric layer 214 can be formed on the rounded fins, such as fin 209 by deposition and patterning techniques, which are known to one of ordinary skill in the art of electronic device manufacturing. The gate dielectric layer, such as gate dielectric 214 can be any well-known gate dielectric layer, as described above with respect to FIG. 1. In an embodiment, the high-k dielectric layer is blanket deposited on the rounded fins, such as fin 209 using a CVD, PVD, molecular beam epitaxy, an Atomic Layer Deposition (“ALD”), any other blanket deposition technique, or a combination thereof. In one embodiment, the thickness of the gate dielectric layer, such as gate dielectric 214 is in the approximate range between about 2 Å to about 100 Å, and more specifically, between about 5 Å to about 30 Å.

FIG. 2H is a view 270 similar to FIG. 2G after a gate electrode is deposited on the gate dielectric layer according to one embodiment of the invention. In an embodiment, a gate electrode layer 215 is subsequently formed on the gate dielectric layer, such as gate dielectric layer 214 by deposition and patterning techniques, which are known to one of ordinary skill in the art of transistor fabrication. In an embodiment, the thickness of the gate electrode 215 is from about 500 Å and 5000 Å. The gate electrode 215 can be gate electrode 107, as described above with respect to FIG. 1. In one embodiment, a source region and a drain region (not shown) are formed on each of the rounded fins, such as fin 209 at opposite sides of the gate electrode, such as gate electrode 215, as described above with respect to FIG. 1.

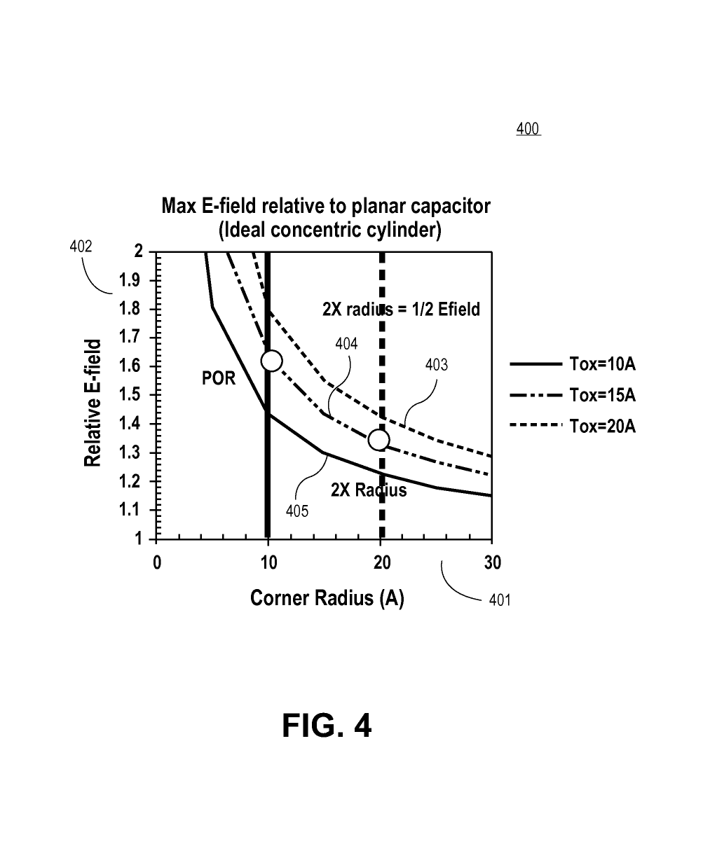

FIG. 4 is a graph 400 showing a relative electric field in a gate dielectric versus a corner radius of curvature according to one embodiment of the invention. As shown in FIG. 4, relative electric field 402 is calculated as a maximum electric field for an ideal concentric cylinder relative to planar capacitor. The corner radius is about 0 Å for a very sharp corner having about a zero degree acute angle. The corner radius is about infinity for a substantially flat surface having about a 180 degrees obtuse angle. As shown in FIG. 4, a relative electric field in the gate dielectric 402 decreases as a corner radius of curvature of a fin 402 increases for all gate o thicknesses, such as gate oxide thicknesses (Tₒₓ) 10 Å (a curve 405), 15 Å (a curve 404), and 20 Å (a curve 403). In one embodiment, a reduction of relative electric field 402 with increase of corner radius 401 is greater for thicker gate oxide, as shown in FIG. 4. As the corner radius increases from 10 Å to 20 Å, relative electric field decreases from about 1.8 to about 1.45 for Tₒₓ=20 Å (curve 403), relative electric field decreases from about 1.65 to about 1.4 for Tₒₓ=15 Å, and relative electric field decreases from about 1.45 to about 1.25 for Tₒₓ=10 Å. As shown in FIG. 4, increasing the radius of curvature by a factor of two (e.g., from 10 nm to 20 nm) decreases the relative electric field in the gate dielectric by 60%. As shown in FIG. 4, doubling the corner radius of curvature can reduce the corner electric field enhancement by at least a factor of two. That is, smoothening the corner of the fin substantially reduces the electric field in the gate dielectric.

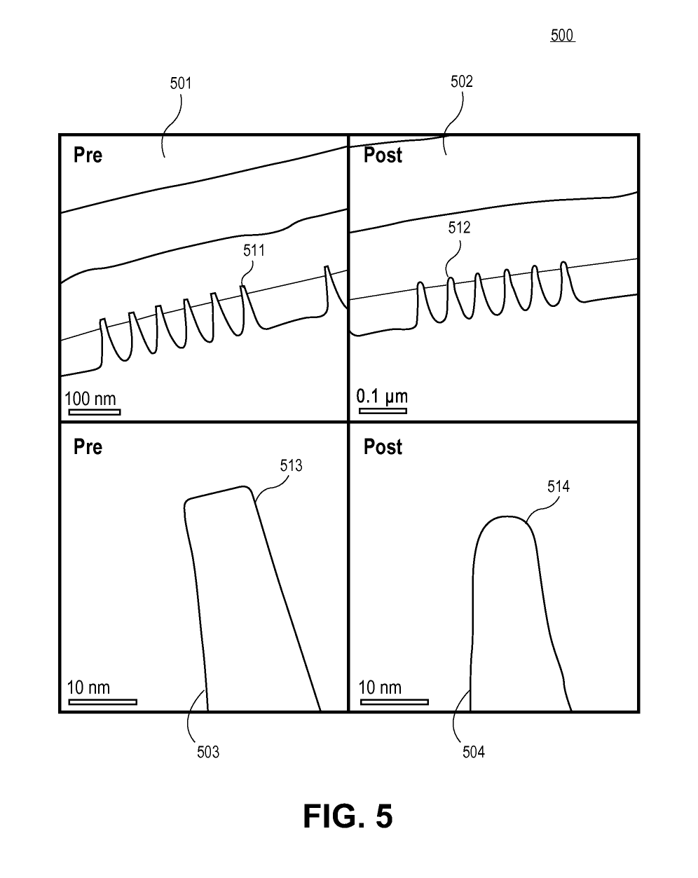

FIG. 5 shows exemplary images 500 of the fins for the tri-gate array before and after smothering the corners according to one embodiment of the invention. Images 501 and 503 show fins, such as a fin 511 and a 513 before smothering the corners. Fin 511 and 513 have sharp corners, as shown in FIG. 5. Images 502 and 504 show fins, such as a fin 512 and 514 after smothering the corners by a gentle sputter process as described herein. As shown in images 502 and 504, the fins 512 and 514 have rounded corners.

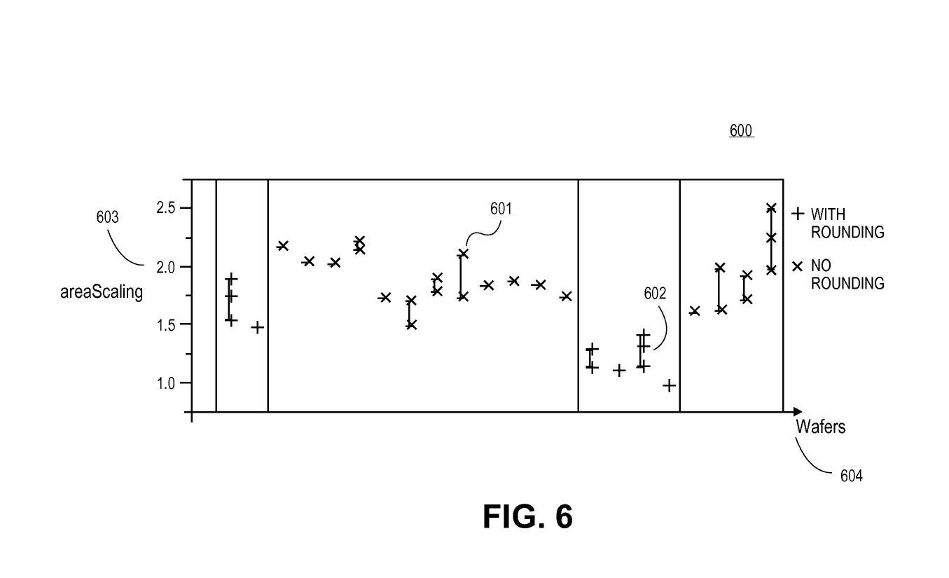

FIG. 6 shows an exemplary area scaling chart for wafers according to one embodiment of the invention. Typically, area scaling chart is provided by measuring a failure rate of a transistor array as a function of its area. Greater wafer area accommodates more transistors. Generally, the area scaling represents a failure rate that is determined by measuring time dependent dielectric breakdown (TDDB) for large transistor arrays. As shown in FIG. 6, area scaling (failure rate) for tri-gate transistor wafer arrays having rounded fins (602) according to embodiments described herein is decreased comparing to area scaling (failure rate) 603 for conventional tri-gate gate transistor array wafers (603). As shown in FIG. 6, the area scaling is reduced by at least a factor of two (e.g., from about 1.8-2.0 to about 1.1-1.2) for the tri-gate transistor arrays having the rounded fins according to embodiments as described herein.

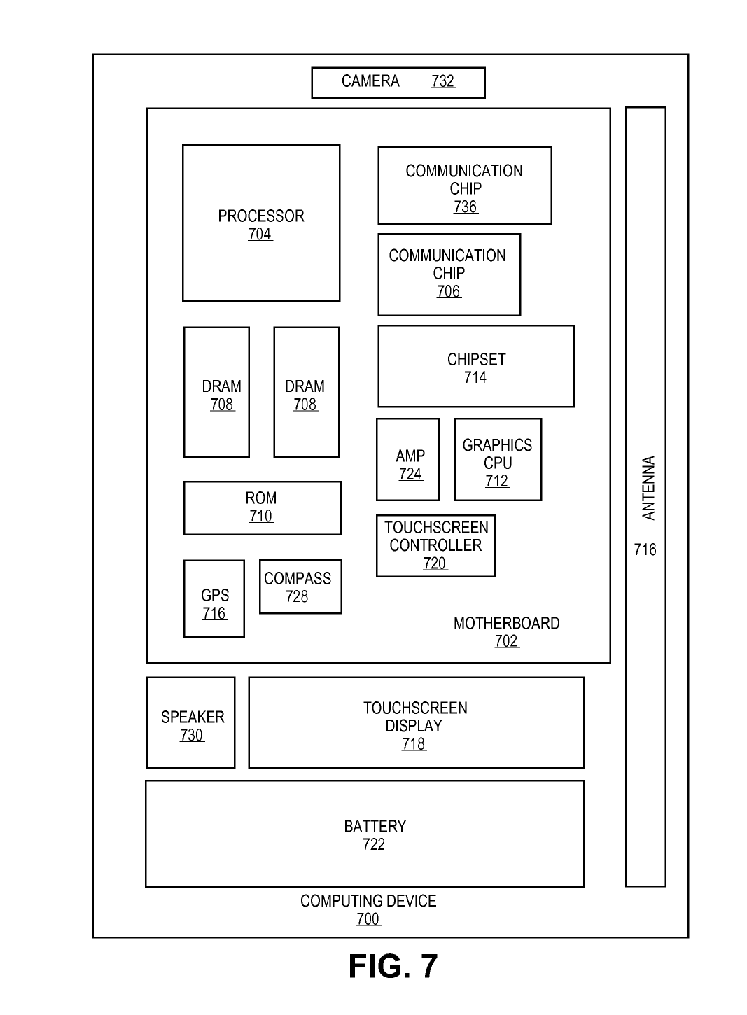

FIG. 7 illustrates a computing device 700 in accordance with one embodiment. The computing device 700 houses a board 702. The board 702 may include a number of components, including but not limited to a processor 704 and at least one communication chip 706. The processor 704 is physically and electrically coupled to the board 702. In some implementations the at least one communication chip is also physically and electrically coupled to the board 702. In further implementations, at least one communication chip 706 is part of the processor 704.

Depending on its application, computing device 700 may include other components that may or may not be physically and electrically coupled to the board 702. These other components include, but are not limited to, a memory, such as a volatile memory 708 (e.g., a DRAM), a non-volatile memory 710 (e.g., ROM), a flash memory, a graphics processor 712, a digital signal processor (not shown), a crypto processor (not shown), a chipset 714, an antenna 716, a display, e.g., a touchscreen display 718, a display controller, e.g., a touchscreen controller 720, a battery 722, an audio codec (not shown), a video codec (not shown), an amplifier, e.g., a power amplifier 724, a global positioning system (GPS) device 726, a compass 728, an accelerometer (not shown), a gyroscope (not shown), a speaker 1130, a camera 732, and a mass storage device (such as hard disk drive, compact disk (CD), digital versatile disk (DVD), and so forth) (not shown).

A communication chip, e.g., communication chip 706, enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips. For instance, a communication chip 706 may be dedicated to shorter range wireless communications such as Wi-Fi and Bluetooth and a communication chip 736 may be dedicated to longer range wireless communications such as GPS, EDGE, GPRS, CDMA, WiMAX, LTE, Ev-DO, and others.

In at least some embodiments, the processor 704 of the computing device 700 includes an integrated circuit die having a tri-gate transistor array with the improved TDDB area scaling according to embodiments described herein. The integrated circuit die of the processor includes one or more devices, such as transistors or metal interconnects as described herein. The term “processor” may refer to any device or portion of a device that processes electronic data from registers and/or memory to transform that electronic data into other electronic data that may be stored in registers and/or memory.

The communication chip 1006 also includes an integrated circuit die package having a tri-gate transistor array with the improved TDDB area scaling according to embodiments according to the embodiments described herein.

In further implementations, another component housed within the computing device 1000 may contain an integrated circuit die package having a tri-gate transistor array with the improved TDDB area scaling according to embodiments according to the embodiments described herein.

In accordance with one implementation, the integrated circuit die of the communication chip includes one or more devices, such as transistors and metal interconnects, as described herein. In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

In the foregoing specification, embodiments of the invention have been described with reference to specific exemplary embodiments thereof. It will be evident that various modifications may be made thereto without departing from the broader spirit and scope of embodiments of the invention as set forth in the following claims. The specification and drawings are, accordingly, to be regarded in an illustrative sense rather than a restrictive sense.

1. A method to manufacture a tri-gate transistor, comprising:
depositing an insulating layer on a fin on a substrate, the fin having a corner;
recessing the insulating layer to expose the fin;
rounding off the corner by using a noble gas; and
depositing a gate dielectric layer on the rounded corner.

2. The method of claim 1, wherein the rounding off is performed by a sputter process.

3. The method of claim 1, wherein the rounding off includes
etching the corner while substantially preserving the height of the fin.

4. The method of claim 1, further comprising
depositing a gate electrode on the gate dielectric layer; and
forming a source region and a drain region on the fin at opposite sides of the gate electrode.

5. The method of claim 1, wherein the noble gas is helium (He), neon (Ne), argon (Ar), krypton (Kr), xenon (Xe), radon (Rn), any other inert gas, or a combination thereof.

6. The method of claim 1, wherein the rounded corner has a radius of curvature, and therein the method further comprises
controlling the radius of curvature by adjusting a bias power applied to the substrate.

7. A method to manufacture a tri-gate transistor array, comprising:
forming a plurality of fins on a substrate, the fins having surfaces and corners at the surfaces;
depositing an insulating layer on the fins;
recessing the insulating layer to expose the fins; and
rounding off the corners by a sputter process.

8. The method of claim 7, further comprising
depositing a gate dielectric layer on the rounded corners;
depositing a gate electrode on the gate dielectric layer; and
forming a source region and a drain region on each of the fins at opposite sides of the gate electrode.

9. The method of claim 7, further comprising
adjusting a radius of curvature of the corners by adjusting a bias power applied to the substrate.

10. The method of claim 7, wherein the sputter process includes etching the corners by an inert gas.

11. The method of claim 7, wherein the forming the plurality of fins includes
depositing a hard mask over the substrate;
patterning the hard mask to create openings; and
etching the substrate through the openings.

12. The method of claim 7, further comprising
polishing the insulating layer to expose tops of the fins.

13. The method of claim 7, wherein the rounding off the corners includes etching the corners at a rate that exceeds the rate of etching of the surfaces.

14. The method of claim 7, wherein the rounding off the corners is performed while preserving the height of the fins.

15. A tri-gate transistor array to reduce an area scaling, comprising
a first fin having rounded corners on a substrate, the rounded corners having a radius of curvature;
and
a first gate dielectric layer on the first fin covering the rounded corners, wherein the radius of curvature of the rounded corners is adjusted to at least 20 percent of a width of the first fin; and
a gate electrode on the gate dielectric layer.

16. The tri-gate transistor array of claim 15, further comprising
a source region and a drain region at opposite sides of the gate electrode.

17. The tri-gate transistor array of claim 15, further comprising
a second fin having the rounded corners on the substrate;
a second gate dielectric layer on the second fin covering the rounded corners; and
an insulating layer between the first fin and the second fin,
wherein the radius of curvature is adjusted to reduce the area scaling of the array by at least 60%.

18. The tri-gate transistor array of claim 15, wherein the radius is adjustable by a sputter process.

19. The tri-gate transistor array of claim 15, wherein the first fin has a height that is independent from the width.

20. The tri-gate transistor array of claim 15, wherein the fin width is in a range from 5 nm to 50 nm.
